(19) United States
(12) Patent Application Publication
(10) Pub. No.: US 2024/0318303 A1
(43) Pub. Date: Sep. 26, 2024

(54) SURFACE TREATMENT APPARATUS

(71) Applicant: Shibaura Machine Co., Ltd., Tokyo (JP)

(72) Inventors: Kazuhiro FUKADA, Numazu (JP); Yoshiaki KURIHARA, Numazu (JP); Takeshi NAMBA, Numazu (JP); Satoshi FUKUYAMA, Numazu (JP); Mitsunori KOKUBO, Numazu (JP)

(73) Assignee: Shibaura Machine Co., Ltd., Tokyo (JP)

(21) Appl. No.: 18/580,544

(22) PCT Filed: Sep. 20, 2022
(86) PCT No.: PCT/JP2022/034899

§ 371 Date: Jan. 18, 2024

(30) Foreign Application Priority Data
Sep. 28, 2021 (JP) 2021-158047

(51) Int. Cl. C23C 14/56; C23C 14/34; C23C 14/50

(52) U.S. Cl. CPC C23C 14/568; C23C 14/34; C23C 14/50; C23C 14/566

(57) ABSTRACT

A surface treatment apparatus includes a placement part on which a workpiece is placed, a first housing part, a second housing part, and a conveyance part. The first housing part houses the workpiece placed on the placement part. The second housing part houses the workpiece placed on the placement part. The second housing part includes a surface treatment part performing at least one type of surface treatment. The conveyance part conveys the workpiece placed on the placement part in a longitudinal direction of the first housing part or the second housing part. The surface treatment apparatus performs surface treatment on the workpiece in a state where the second housing part is a single body or in a state where the first housing part and the second housing part are plurally coupled in a conveyance direction of the conveyance part.

### TECHNICAL FIELD

The present invention relates to a surface treatment apparatus that performs surface treatment on a workpiece.

### BACKGROUND ART

Conventionally, a surface treatment apparatus for depositing a metal catalyst layer, a SiOx film, or the like by cleaning or modifying a surface of a workpiece by using plasma, and a surface treatment apparatus for depositing a thin film on a surface of a workpiece by using a sputtering device, have been known.

For example, Patent Literature 1 discloses a film deposition apparatus that deposits a film on one surface of a workpiece.

### CITATION LIST

### Patent Literature

Patent Literature 1: JP 2015-098617 A

### SUMMARY OF INVENTION

### Problem to be Solved by the Invention

When performing film deposition on both surfaces of a workpiece, it is desirable that the workpiece can be treated without being exposed to the atmosphere as much as possible. However, for example, in the film deposition apparatus of Patent Literature 1, it is necessary to invert the direction of the workpiece and deposit film again after the film deposition on one side is completed. Further, when a conventional single-sided film deposition apparatus is diverted to a double-sided film deposition apparatus, a new design is required, and thus there is a problem that film deposition conditions accumulated in the single-sided film deposition apparatus cannot be used as they are.

The present invention has been made in view of the above, and an object thereof is to provide a surface treatment apparatus capable of directly by using film deposition conditions of a single-sided film deposition apparatus for a double-sided film deposition apparatus.

### Means for Solving Problem

For solving the above-described problem and achieving the object, a surface treatment apparatus according to the present invention includes: a placement part on which a workpiece is placed; a first housing part that houses the workpiece placed on the placement part; a second housing part that houses the workpiece placed on the placement part and includes a surface treatment part performing at least one type of surface treatment; and a conveyance part that conveys the workpiece placed on the placement part in a longitudinal direction of the first housing part or the second housing part, wherein the surface treatment apparatus performs surface treatment on the workpiece in a state where the second housing part is a single body or in a state where the first housing part and the second housing part are plurally coupled in a conveyance direction of the conveyance part.

### Effect of the Invention

A surface treatment apparatus according to the present invention brings an effect that film deposition conditions of a single-sided film deposition apparatus can be directly applied to a double-sided film deposition apparatus.

### BRIEF DESCRIPTION OF DRAWINGS

FIG. 1 is a schematic configuration view of a surface treatment apparatus that performs single-sided film deposition;

FIG. 2 is a top view of an inside of a chamber of the surface treatment apparatus of FIG. 1;

FIG. 3 is an exploded perspective view illustrating an example of an attachment structure of a workpiece;

FIG. 4 is a cross-sectional view illustrating an example of the attachment structure of the workpiece;

FIG. 5 is a cross-sectional view illustrating an example of a configuration of a plasma treatment device;

FIG. 6 is a cross-sectional view illustrating an example of a configuration of a sputtering device;

FIG. 7 is a side view illustrating an example of a configuration of a pump part;

FIG. 8 is a top view illustrating an example of a configuration of a single surface treatment apparatus;

FIG. 9 is a top view illustrating an example of a state where two surface treatment apparatuses are coupled;

FIG. 10 is a top view illustrating an example of a state where a load lock chamber is coupled to the surface treatment apparatus illustrated in FIG. 9;

FIG. 11 is a top view illustrating another example of a state where a load lock chamber is coupled to the surface treatment apparatus illustrated in FIG. 9;

FIG. 12 is a view illustrating an example of a configuration in which each of coupled surface treatment apparatuses includes an exhaust device;

FIG. 13 is a view illustrating an example of a configuration in which one of the coupled surface treatment apparatuses includes an exhaust device;

FIG. 14 is a view illustrating an example of a configuration in which an exhaust device is provided on a piping member that couples openings of coupled surface treatment apparatuses to each other;

FIG. 15 is a view illustrating an example of a configuration in which a pump part is provided on a piping member that couples openings of coupled surface treatment apparatuses to each other, and a lifting valve is provided in each of the openings of the surface treatment apparatuses;

FIG. 16 is a top view illustrating an example of a schematic configuration of a surface treatment apparatus that is a first modification of the embodiment;

FIG. 17 is a top view illustrating an example of a schematic configuration of a surface treatment apparatus that is a second modification of the embodiment;

FIG. 18 is a top view illustrating an example of a schematic configuration of a surface treatment apparatus that is a third modification of the embodiment; and

FIG. 19 is a top view illustrating an example of a schematic configuration of a surface treatment apparatus that is a fourth modification of the embodiment.

### DESCRIPTION OF EMBODIMENTS

Hereinafter, an embodiment of a surface treatment apparatus according to the present disclosure will be described in detail with reference to the drawings. Note that the present invention is not limited by the embodiment. Further, components in the following embodiments include those that can be replaced by those skilled in the art and can be easily conceived, or those that are substantially the same.

### Embodiment

In the embodiment of the present disclosure, a desired surface treatment is performed on both surfaces of a workpiece W (work) formed by a resin material such as, for example, a plastic resin, by coupling plural surface treatment apparatuses 10 each performing surface treatment on one surface of the workpiece W. Hereinafter, a single surface treatment apparatus is referred to as a surface treatment apparatus 10, and a surface treatment apparatus in which plural surface treatment apparatuses 10 are coupled is referred to as a surface treatment apparatus 10a or 10b. Note that the surface treatment of the workpiece W is, for example, a film deposition treatment.

### [1. Single Structure of Surface Treatment Apparatus]

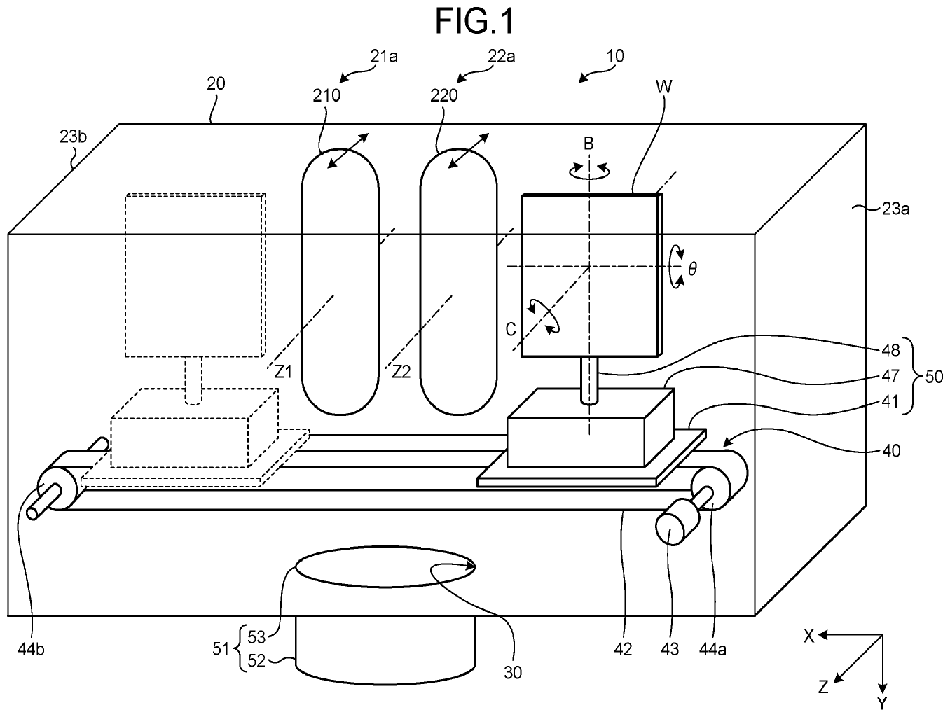

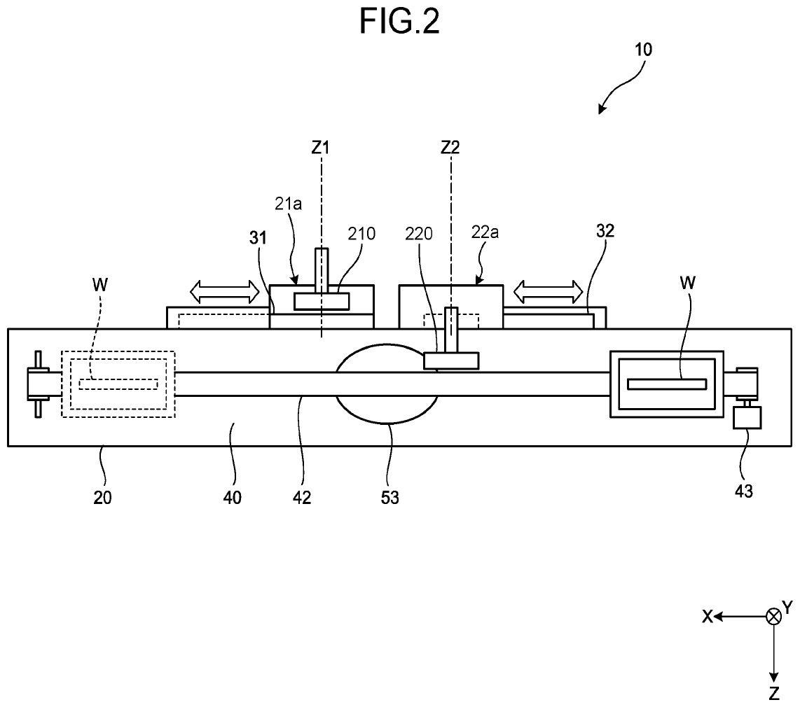

First, a schematic configuration of a single surface treatment apparatus 10 will be described by using FIGS. 1 and 2. FIG. 1 is a schematic configuration view of a surface treatment apparatus that performs single-sided film deposition. FIG. 2 is a top view of the inside of a chamber of the surface treatment apparatus of FIG. 1.

The surface treatment apparatus 10 includes a workpiece placement part 50, a workpiece conveyance part 40, a hollow cathode discharge (HCD) electrode 210, and a sputtering electrode 220 contained in a chamber 20.

The chamber 20 is a sealed reaction container in which surface treatment is performed on the workpiece W stored inside. The chamber 20 has a rectangular parallelepiped shape whose longitudinal direction is an X-axis direction in an XYZ coordinate system illustrated in FIG. 1. Note that the chamber 20 is an example of a second housing part in the present disclosure.

The workpiece placement part 50 places the workpiece W in a state of being substantially erected along the Y-axis. Note that the workpiece placement part 50 is an example of a placement part in the present disclosure. The workpiece placement part 50 includes a moving table 41, an attachment table 47, and an attachment shaft 48.

The moving table 41 is a base on which the workpiece W is placed. The moving table 41 is conveyed along the X-axis by the workpiece conveyance part 40 described later.

The attachment table 47 is a member that is installed on the moving table 41 and serves as a base for attaching the workpiece W.

The attachment shaft 48 supports the workpiece W on the attachment table 47.

Note that the workpiece placement part 50 may include an adjustment mechanism that adjusts the direction of the workpiece W with respect to the HCD electrode 210 or the sputtering electrode 220 described later by swinging the direction of the workpiece W around the axis B illustrated in FIG. 1. Further, the workpiece placement part 50 may include an adjustment mechanism that adjusts the direction of the workpiece W around the axis C illustrated in FIG. 1, that is, around the normal direction of the workpiece W. Moreover, the workpiece placement part 50 may include an adjustment mechanism that adjusts the direction of the workpiece W around the axis θ illustrated in FIG. 1. By providing these adjustment mechanisms, it is possible to more uniformly deposit a film on the surface of the workpiece W.

The workpiece conveyance part 40 conveys the workpiece W placed on the workpiece placement part 50 in the longitudinal direction (X-axis) of the chamber 20. Note that the workpiece conveyance part 40 is an example of a conveyance part in the present disclosure.

The workpiece conveyance part 40 is a single-axis moving table driven by a conveyance motor 43. Specifically, the workpiece conveyance part 40 conveys the moving table 41 fixed to a timing belt 42 stretched between two pulleys 44a and 44b along the X-axis by a rotational driving force of the conveyance motor 43.

The workpiece W is placed on the moving table 41 via the attachment table 47 and the attachment shaft 48, so that the workpiece W is conveyed along the X-axis by the workpiece conveyance part 40.

A plasma treatment device 21 and a sputtering device 22 are installed on one side surface along an XY plane of the chamber 20.

The plasma treatment device 21 performs surface treatment of the workpiece W by irradiating the workpiece W with plasma generated by the HCD electrode 210. By this surface treatment, for example, a SiO₂ layer is generated on the surface of the workpiece W. Therefore, environmental resistance of the surface of the workpiece W is improved. Note that the plasma treatment device 21 is an example of a surface treatment part in the present disclosure.

The HCD electrode 210 is movable along an axis Z1 that is parallel to a Z-axis. With this configuration, more uniform film deposition treatment can be performed by setting the interval between the workpiece W and the HCD electrode 210 to an optimum value.

The sputtering device 22 performs sputtering by ejecting atoms to be used for film deposition from the target placed on the sputtering electrode 220 and bringing the ejected atoms into close contact with the surface of the workpiece W. By sputtering, for example, a thin film serving as a base for plating is formed on the surface of the workpiece W. Note that the sputtering device 22 is an example of a surface treatment part in the present disclosure.

The sputtering electrode 220 is movable along an axis Z2 parallel to the Z-axis. With this configuration, by setting the interval between the workpiece W and the sputtering electrode 220 to an optimum value, more uniform film deposition treatment can be performed.

An exhaust device 51 is installed on a bottom surface of the chamber 20. The exhaust device 51 decompresses the inside of the chamber 20 into a vacuum state. Further, the exhaust device 51 discharges gas (reaction gas) filling the inside of the chamber 20 by surface treatment. The exhaust device 51 includes a pump part 52 and a lifting valve 53. The pump part 52 is attached to the bottom surface of the chamber 20, and adjusts the pressure of an inside of the chamber 20 and exhausts the gas filling the inside of the chamber 20 by an operation of the plasma treatment device 21 or the sputtering device 22. The pump part 52 is configured by, for example, a rotary pump or a turbo molecular pump. For example, by moving between a state of being in contact with the bottom surface of the chamber 20 and a state of moving to a negative side of the Y-axis, the lifting valve 53 opens an opening 30 formed in the bottom surface of the chamber 20 to the atmosphere. Note that the exhaust device 51 is an example of an exhaust part in the present disclosure. Further, the pump part 52 is an example of a pump device in the present disclosure. The lifting valve 53 is an example of a valve member in the present disclosure.

Both side surfaces of the chamber 20 along an YZ plane include opening-closing doors 23a and 23b. The opening-closing doors 23a and 23b can be opened and closed by a hinge mechanism or a slide mechanism. The operator of the surface treatment apparatus 10 opens and closes the opening-closing doors 23a and 23b to place the workpiece W and take out the workpiece W having completed the surface treatment.

The surface treatment apparatus 10 further includes a cooling device, a control device, a power supply device, a gas supply device, an operation panel, and the like, which are not illustrated in order to simplify the description.

The cooling device generates cooling water for cooling equipment, a power supply, and the like.

The control device controls the entire surface treatment apparatus 10.

The power supply device houses power to be supplied to each part of the surface treatment apparatus 10.

The gas supply device supplies a film deposition gas and a reaction gas to the chamber 20.

The operation panel receives an operation instruction to the surface treatment apparatus 10. Further, the operation panel has a function to display an operating state of the surface treatment apparatus 10.

The chamber 20 includes a shutter 31 and a shutter 32 illustrated in FIG. 2. Note that the shutters 31 and 32 are examples of a shielding member in the present disclosure.

By moving to a positive side of the X-axis, the shutter 31 exposes the HCD electrode 210 when plasma treatment is performed on the workpiece W. Further, by moving to a negative side of the X-axis, the shutter 31 stores the HCD electrode 210 when the sputtering treatment is performed on the workpiece W. Therefore, contamination of electrodes that are not used is prevented.

By moving to the negative side of the X-axis, the shutter 32 exposes the sputtering electrode 220 when the sputtering treatment is performed on the workpiece W. Further, by moving to the positive side of the X-axis, the shutter 32 stores the sputtering electrode 220 when plasma treatment is performed on the workpiece W. Therefore, contamination of electrodes that are not used is prevented.

Note that, during the film deposition, it is desirable that the HCD electrode 210 is not moved in the direction of the axis Z1 and the sputtering electrode 220 is not moved in the direction of the axis Z2, but the delivery amounts in the directions of the axis Z1 and the axis Z2 may be appropriately changed with the degree of vacuum inside the chamber 20, the gas flow rate, the conveyance speed of the workpiece W, the power, the voltage value, the current value, the discharge state, the temperature inside the chamber 20, and the like. Therefore, more uniform film deposition treatment can be performed. Further, the conveyance speed of the workpiece W may be changed in accordance with the value of each parameter described above.

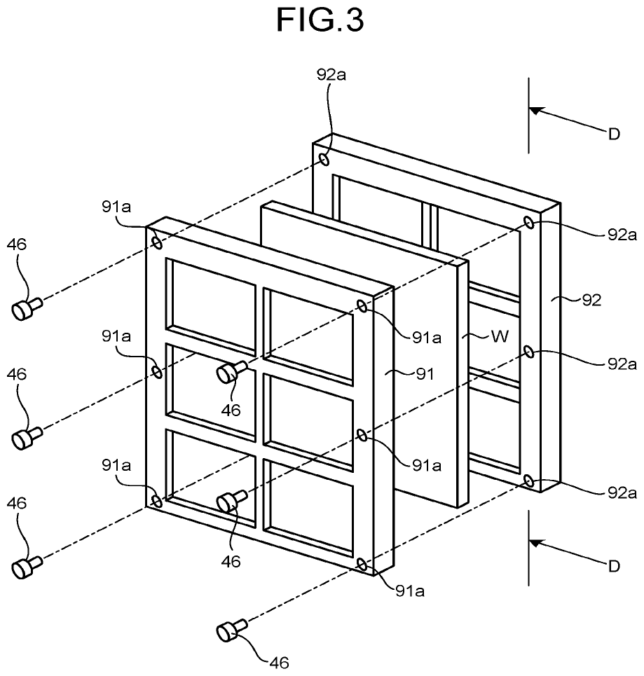

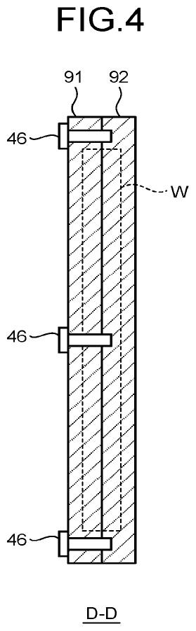

Next, an attachment structure of the workpiece W will be described by using FIGS. 3 and 4. FIG. 3 is an exploded perspective view illustrating an example of the attachment structure of the workpiece. FIG. 4 is a cross-sectional view illustrating an example of the attachment structure of the workpiece.

As illustrated in FIG. 3, the workpiece W is attached to the workpiece placement part 50 while being clamped between two base material holders 91 and 92.

The base material holders 91 and 92 are plate-shaped members in which lattice-shaped openings are formed. As illustrated in FIG. 4, in the base material holders 91 and 92, the side abutting on the workpiece W is formed to be thin in accordance with the shape of the workpiece W. Accordingly, when the workpiece W is clamped between the base material holders 91 and 92, the workpiece W is reliably clamped between the two base material holders 91 and 92. Then, the workpiece W clamped between the base material holders 91 and 92 is subjected to surface treatment at positions corresponding to the lattice-shaped openings.

A plurality of attachment holes 91a through which screws 46 pass is formed in an outer edge of the base material holder 91. Then, the screw 46 inserted into an attachment hole 91a is coupled with a female screw 92a formed in the base material holder 92 to fix the base material holder 91 and the base material holder 92 in a state of clamping the workpiece W. Note that the base material holder 91 and the base material holder 92 may be fixed by using a one-touch clip or the like instead of the screw 46.

Note that, in a case where the treatment is to be performed only on one surface of the workpiece W, the opening may not be formed in the base material holder on the side not to be subjected to the surface treatment on the workpiece W.

### [2. Structure of Plasma Treatment Device]

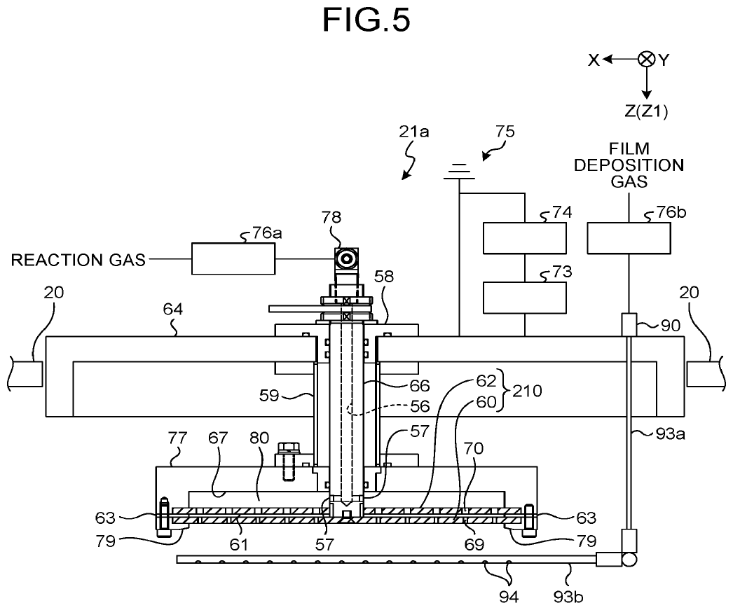

A configuration of the plasma treatment device 21 will be described by using FIG. 5. FIG. 5 is a cross-sectional view illustrating an example of a configuration of a plasma treatment device.

The plasma treatment device 21 includes a gas supply pipe 66 for supplying a reaction gas such as argon used for generating a plasma gas, and a pair of plate-shaped conductor parts 60 and 62 for generating a plasma gas from the reaction gas supplied from the gas supply pipe 66 by a high-frequency voltage. Note that, as the reaction gas, for example, oxygen, argon, nitrogen, or the like is used alone or in a mixed state.

The gas supply pipe 66 penetrates a support plate 64 supported on a side wall surface of the chamber 20 so as to be movable along the Z-axis (Z1-axis) in a thickness direction, and is attached to the support plate 64 by a gas supply pipe attachment member 58. Further, a gas flow path 56 in an extending direction of the gas supply pipe 66 is formed inside the gas supply pipe 66, and the reaction gas is supplied from the outside of the chamber 20 into the chamber 20 through the gas flow path 56. Note that a gas supply part 78 that supplies a reaction gas to the gas supply pipe 66 is connected to an end of the gas supply pipe 66 on an outside (outside of the chamber 20) of the support plate 64, and a gas supply hole 57 that is a hole for introducing the reaction gas flowing through the gas flow path 56 into the chamber 20 is formed at an end of the gas supply pipe 66 on the other end side (inner side of the chamber 20). A reaction gas is supplied to the gas supply part 78 through a mass flow controller (MFC) 76a in which the mass flowmeter has a flow rate control function.

Each of the pair of plate-shaped conductor parts 60 and 62 is formed in a flat plate shape, and is formed by disposing a metal plate of aluminum or the like or another conductor plate in parallel. The plate-shaped conductor parts 60 and 62 are supported by a support plate 77. Note that the pair of plate-shaped conductor parts 60 and 62 is an example of an electrode (HCD electrode 210) in the present disclosure. The support plate 77 is formed by, for example, an insulating material such as glass or ceramic. The support plate 77 is formed in a shape in which a protrusion is formed over the entire periphery near the outer periphery on the support plate 64 side. In other words, the support plate 77 is formed in a plate-like shape in which a recess 67 recessed along the outer periphery of the support plate 77 is formed inside the chamber 20.

The support plate 77 is supported by a support member 59. The support member 59 includes a cylindrical member and attachment members located at both ends of the cylindrical member, in which an end on a negative side of the Z-axis is attached to the support plate 64, and an end on a positive side of the Z-axis is attached to the support plate 77.

The gas supply pipe 66 penetrating the support plate 64 passes through the inside of the cylindrical support member 59, extends to the position of the support plate 77, and penetrates the support plate 77. Then, the gas supply hole 57 formed in the gas supply pipe 66 is disposed in a part of the support plate 77 where the recess 67 is formed.

The pair of plate-shaped conductor parts 60 and 62 is disposed on the side of the support plate 77 where the recess 67 is formed so as to cover the recess 67. A spacer 63 is interposed between the pair of plate-shaped conductor parts 60 and 62, and the plate-shaped conductor parts 60 and 62 are overlapped with each other through the spacer 63. Then, the pair of plate-shaped conductor parts 60 and 62 is disposed apart from each other in a part other than the spacer 63 to form a gap part 61 between the plate-shaped conductor parts 60 and 62. An interval of the gap part 61 is preferably appropriately set in accordance with the frequency of the reaction gas introduced in the plasma treatment device 21 or the power to be supplied, the size of the electrode, and the like, and is, for example, about 3 mm to 12 mm.

The pair of plate-shaped conductor parts 60 and 62 is held by a holding member 79 which is a member for holding the plate-shaped conductor parts 60 and 62 in a state of being overlapped with each other while interposing the spacer 63. That is, the holding member 79 is disposed on the opposite side of the side where the support plate 77 is located on the plate-shaped conductor parts 60 and 62, and is attached to the support plate 77 in a state where the plate-shaped conductor parts 60 and 62 are clamped between the holding member 79 and the support plate 77. Then, a space is formed between the recess 67 of the support plate 77 and the plate-shaped conductor parts 60 and 62.

The space thus formed functions as a gas introduction part 80 into which the reaction gas supplied by the gas supply pipe 66 is introduced. The gas supply hole 57 of the gas supply pipe 66 is located in the gas introduction part 80 and is opened toward the gas introduction part 80.

Further, a large number of through holes 69 and 70 penetrating in the thickness direction are formed in the pair of plate-shaped conductor parts 60 and 62, respectively. That is, in the plate-shaped conductor part 62 located on the inflow side of the reaction gas supplied by the gas supply pipe 66, a plurality of through holes 70 is formed at predetermined intervals in a matrix form when viewed in the thickness direction of the plate-shaped conductor part 62, and in the plate-shaped conductor part 60 located on the outflow side of the reaction gas supplied by the gas supply pipe 66, a plurality of through holes 69 is formed at predetermined intervals in a matrix form when viewed in the thickness direction of the plate-shaped conductor part 60.

Each of the through holes 69 of the plate-shaped conductor part 60 and the through holes 70 of the plate-shaped conductor part 62 is a cylindrical hole, and both the through holes 69 and 70 are coaxially arranged. That is, the through holes 69 of the plate-shaped conductor part 60 and the through holes 70 of the plate-shaped conductor part 62 are arranged at positions where the centers of the respective through holes are aligned. Among these, the through holes 69 of the plate-shaped conductor part 60 are smaller in diameter than the through holes 70 of the plate-shaped conductor part 62 on the inflow side of the reaction gas. As described above, the pluralities of through holes 69 and 70 are formed in the pair of plate-shaped conductor parts 60 and 62 to form a hollow electrode structure, and the generated plasma gas flows at high density through the pluralities of through holes 69 and 70.

The gap part 61 is interposed between the parallel plate-shaped conductor parts 60 and 62, but the gap part 61 functions as a capacitor having electrostatic capacitance. Then, a conductive part (not illustrated) is formed on the support plate 77 and the plate-shaped conductor parts 60 and 62 by a conductive member, and the support plate 77 is grounded 75 and the plate-shaped conductor part 62 is also grounded 75 by the conductive part. Further, one end of a high frequency power supply (RF) 74 is grounded 75, and another end of the high frequency power supply 74 is electrically connected to the plate-shaped conductor part 60 via a matching box (MB) 73 for adjusting capacitance and the like to obtain matching with plasma. Therefore, when the high frequency power supply 74 is operated, the potential of the plate-shaped conductor part 60 swings positively and negatively at a predetermined frequency such as 13.56 MHz.

The generated plasma gas flows out from the through holes 70. Then, on the positive side of the Z-axis of the through holes 70, the plasma gas flowing out reacts with the film deposition gas jetted toward the positive side of the Z-axis from a plurality of gas supply holes 94 formed in a gas supply pipe 91b parallel to the plate-shaped conductor parts 60 and 62, that is, extending along the X-axis.

The film deposition gas is introduced into the chamber 20 from a port 90 via a mass flow controller (MFC) 76b. The film deposition gas is supplied by a gas supply pipe 93a extending along the Z-axis and a gas supply pipe 93b extending along the X-axis.

Note that, as the film deposition gas, a substance corresponding to the surface treatment performed by the surface treatment apparatus 10 is used. For example, methane, acetylene, butadiene, titanium tetraisopropoxide (TTIP), hexamethyldisiloxane (HMDSO), tetraethoxysilane (TEOS), hexamethyldisilazane (HMDS), tetramethylsilane (TMS), and the like are used. Then, surface treatment such as film deposition and cleaning of the workpiece W in the chamber 20 is performed by a precursor generated by reaction between the plasma gas and the film deposition gas.

### [3. Structure of Sputtering Device]

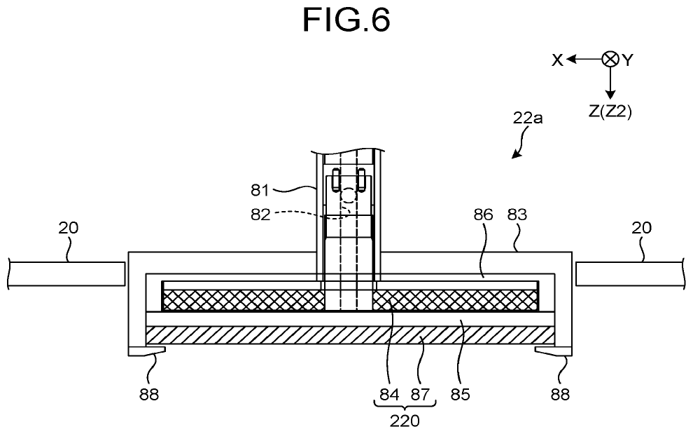

A configuration of the sputtering device 22 will be described by using FIG. 6. FIG. 6 is a cross-sectional view illustrating an example of a configuration of the sputtering device.

The sputtering device 22 includes a cooling water pipe 81, a magnet 84, a target 87, a cooling jacket 85, and a support plate 83.

The cooling water pipe 81 forms a flow path of cooling water to be supplied to the cooling jacket 85.

The magnet 84 generates a magnetic field.

The target 87 ejects atoms to be used for film deposition by ionizing and colliding an inert gas (for example, argon) supplied from the gas supply device that is not illustrated in FIG. 1 and flowing in from a gas inflow part that is not illustrated in FIG. 6 inside a magnetic field generated by the magnet 84. Note that the target 87 is, for example, a copper plate, and copper atoms ejected from the target 87 are brought into close contact with the surface of the workpiece W to form a copper thin film on the surface of the workpiece W. Note that the magnet 84 and the target 87 are examples of an electrode (sputtering electrode 220) in the present disclosure.

The cooling jacket 85 cools the target 87 by the cooling water supplied through the cooling water pipe 81.

The support plate 83 supports the magnet 84, the target 87, and the cooling jacket 85. Note that the cooling water pipe 81 penetrates a support plate 83 supported on the side wall surface of the chamber 20 so as to be movable along the Z-axis (Z2-axis) in the thickness direction.

A cooling water passage 82 in an extending direction of the cooling water pipe 81 is formed inside the cooling water pipe 81. Note that, although not illustrated in FIG. 6, the cooling water passage 82 includes a water path for supplying cooling water for cooling from the outside of the chamber 20 to the cooling jacket 85, and a water path for discharging the cooling water used for cooling from the cooling jacket 85 to the outside of the chamber 20. In this manner, the cooling water pipe 81 circulates the cooling water between the outside of the chamber 20 and the cooling jacket 85 disposed in the chamber 20. Note that an inflow path and a discharge path of cooling water that is not illustrated in FIG. 6 are connected to an end of the cooling water pipe 81 on the outside of the chamber 20. On the other hand, an end on the other end side (inside the chamber 20) of the cooling water pipe 81 is connected to the cooling jacket 85. A cooling water flow path is formed inside the cooling jacket 85, and the cooling water flows. Therefore, the cooling water circulates between the outside of the chamber 20 and the cooling jacket 85. Note that the cooling water is supplied from a cooling device that is not illustrated in FIG. 1.

A holding member 88 is attached to a lower part of the support plate 83. The holding member 88 holds the outer periphery and the lower surface of the target 87 while the magnet 84, the cooling jacket 85, and the target 87 are stacked in this order toward the negative side the positive side of the Z-axis.

An insulating material 86 is disposed between the support plate 83 and the magnet 84. The insulating material 86 is also disposed on an outer peripheral part of the magnet 84 in plan view. That is, the magnet 84 is held by the support plate 83 and the holding member 88 via the insulating material 86.

The sputtering device 22 performs what is called sputtering to form a thin film on the surface of the workpiece W. When the sputtering device 22 performs sputtering, the inside of the chamber 20 is decompressed by the exhaust device 51 (see FIG. 1), and then a gas used for sputtering is caused to flow into the chamber 20 from the gas supply device that is not illustrated in FIG. 1. Then, the gas in the chamber 20 is ionized by the magnetic field generated by the magnet 84 of the sputtering device 22, and ions collide with the target 87. Thus, atoms of the target 87 are ejected from the surface of the target 87.

For example, in a case where aluminum is used for the target 87, when ions of gas ionized near the target 87 collide with the target 87, the target 87 ejects atoms of aluminum. The atoms of aluminum ejected from the target 87 are directed toward the positive side of the Z-axis. The workpiece W is located at a position facing the surface of the target 87 in the chamber 20, and thus atoms of aluminum ejected from the target 87 move toward the workpiece W to be in close contact with the workpiece W, and are deposited on the surface of the workpiece W. Consequently, a thin film corresponding to the substance for forming the target 87 is formed on the surface of the workpiece W.

### [4. Structure of Pump Part]

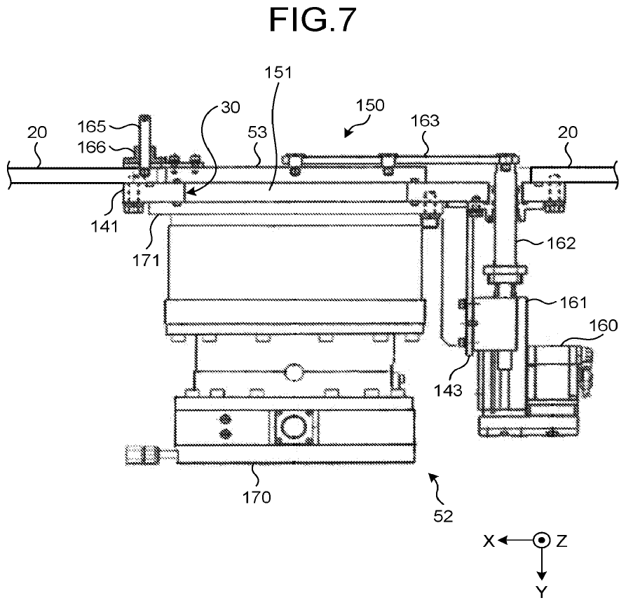

A configuration of the pump part 52 will be described by using FIG. 7. FIG. 7 is a side view illustrating an example of the configuration of the pump part.

The pump part 52 is attached to the bottom surface of the chamber 20, and adjusts the pressure in the chamber 20 and exhausts the gas filling the inside of the chamber 20 by the operation of the plasma treatment device 21 or the sputtering device 22.

The pump part 52 includes a flow rate regulating valve 150 and a turbo molecular pump 170 illustrated in FIG. 7.

The flow rate regulating valve 150 includes a flow path part 151 through which a fluid flows, the lifting valve 53 that opens and closes an opening 30 formed at one end of the flow path part 151, and a servo actuator 160 that performs an opening-closing operation of the lifting valve 53. Further, the turbo molecular pump 170 is a pump that sucks fluid flowing through the flow path part 151 of the flow rate regulating valve 150. The pump part 52 decompresses the inside of the chamber 20 to a desired pressure by adjusting the flow rate of the fluid sucked by the turbo molecular pump 170 with the flow rate regulating valve 150.

The pump part 52 is installed on the bottom part of the chamber 20 by attaching a pump flange 171 formed at an upper end of the turbo molecular pump 170 to an attachment flange 141 installed on the bottom surface of the chamber 20. In a state where the attachment flange 141 is attached to the bottom part of the chamber 20, the opening 30 of the flow path part 151 is open to the inside of the chamber 20, and the flow path part 151 communicates with the inside of the chamber 20.

The flow rate regulating valve 150 includes the lifting valve 53 disposed in the chamber 20, and the servo actuator 160 that is a driving means for moving the lifting valve 53 along the Y-axis in the chamber 20. The lifting valve 53 moves along the Y-axis in the chamber 20 to adjust the flow rate of the fluid to be sucked by the turbo molecular pump 170. Note that the opening-closing operation of the lifting valve 53 is guided by a guide engagement part 166 attached to the lifting valve 53 moving along a valve guide 165, that is, along the Y-axis. The servo actuator 160 is disposed on a surface side of the attachment flange 141 on which the turbo molecular pump 170 is mounted, and is supported by a driving means support part 143.

Further, the flow rate regulating valve 150 includes a lifting shaft 162 to which the lifting valve 53 is coupled via a coupling member 163, and a worm jack 161 that transmits power generated by the servo actuator 160 to the lifting shaft 162 and moves the lifting shaft 162 along the Y-axis. Note that a vacuum gauge that is not illustrated in FIG. 7 is attached to the chamber 20, and the pressure in the chamber 20 is measured by the vacuum gauge. The servo actuator 160 operates on the basis of a measurement value of the vacuum gauge to move the lifting valve 53 along the Y-axis and adjust the flow rate of the fluid to be sucked by the turbo molecular pump 170.

More specifically, the lifting shaft 162, the coupling member 163, and the lifting valve 53 integrally move along the Y-axis to thereby open and close the opening 30. That is, the lifting valve 53 moves to the negative side of the Y-axis to cover the entire opening 30 to thereby close the opening 30. On the other hand, the lifting valve 53 moves to a positive side of the Y-axis to open opening 30.

### [5. Structure of Opening-Closing Door of Surface Treatment Apparatus]

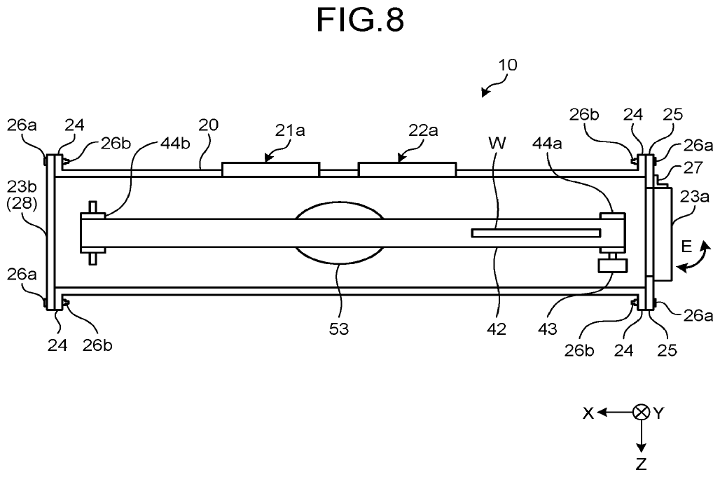

The configuration of the opening-closing doors 23a and 23b of the surface treatment apparatus 10 will be described by using FIG. 8. FIG. 8 is a top view illustrating an example of a configuration of a single surface treatment apparatus.

The opening-closing doors 23a and 23b are installed on the both side surfaces (both end surfaces) along the YZ plane of the chamber 20 constituting the surface treatment apparatus 10.

The opening-closing door 23a is attached to a door frame 25 so as to be openable and closable by a hinge 27. The door frame 25 is fastened to a flange 24 formed at an end of the chamber 20 by a bolt 26a and a nut 26b. Consequently, the opening-closing door 23a is opened and closed in a direction of arrow E. Note that the opening-closing door 23a may be constituted of a shutter movable in a vertical direction (Y-axis direction) or a horizontal direction (Z-axis direction).

On the other hand, a fixed type blank panel 28 is installed on the opening-closing door 23b. The blank panel 28 is fastened to the flange 24 installed at the end of the chamber 20 by the bolt 26a and the nut 26b.

### [6. Coupling Structure of Surface Treatment Apparatus]

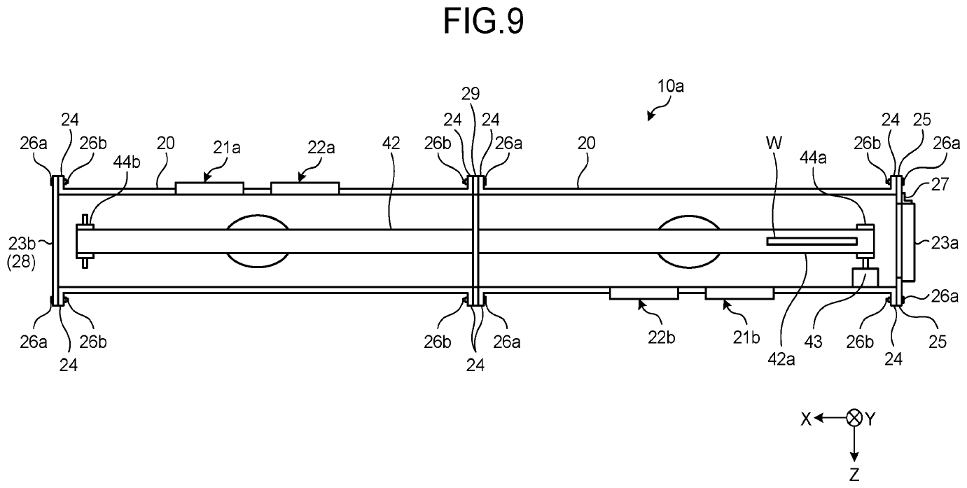

A coupling structure of the surface treatment apparatus 10 will be described by using FIG. 9. FIG. 9 is a top view illustrating an example of a state where two surface treatment apparatuses are coupled.

A surface treatment apparatus 10a illustrated in FIG. 9 is obtained by coupling two surface treatment apparatuses 10 at the positions of the opening-closing doors. Hereinafter, a method of coupling the two surface treatment apparatuses 10 will be described.

First, the opening-closing door 23a and the timing belt 42 of one surface treatment apparatus 10 are removed.

Next, the opening-closing door 23a of the other surface treatment apparatus 10 and the blank panel 28 are removed. Then, the opening-closing door 23a is attached instead of the removed blank panel 28. Further, the timing belt 42 is removed from the surface treatment apparatus 10.

Then, the two surface treatment apparatuses 10 are coupled while interposing a frame member 29 formed by a rigid body between the respective flanges 24. The frame member 29 is formed by, for example, stainless steel or the like, and when the flanges 24 formed at outer edges of the ends of the two chambers 20 to be coupled abut on each other, a region overlapping the openings of the two chambers 20 is opened in a rectangular shape, and a rectangular outer frame is formed at a part abutting on the flange 24. The frame member 29 increases the rigidity of the unitized long chamber when the chambers 20 are coupled. The frame member 29 can suppress bending deformation when the inside of the long chamber is evacuated. Note that the respective flanges 24 of the two coupled surface treatment apparatuses 10 and the frame member 29 are coupled by, for example, one bolt 26a and one nut 26b. That is, in the example of FIG. 9, the two surface treatment apparatuses 10 are coupled in a state where one surface treatment apparatus 10 is turned by 180 degrees around the Y-axis which is an axis perpendicular to an XZ plane to form a long chamber. Note that the method of connecting the frame member 29 and the flange 24 is not limited to the above method. For example, the flanges 24 interposing the frame member 29 are bolted from the both outsides of the flanges 24. Moreover, in a state where the two flanges 24 and the frame member 29 are connected, a reinforcing member along the X-axis may be further connected to an end surface along the Y-axis or the Z-axis.

Next, a timing belt 42a is attached to the two coupled surface treatment apparatuses 10. The timing belt 42a has a length capable of conveying the workpiece W across the inside of the two coupled chambers 20. Note that the conveyance motor 43 and the pulleys 44a and 44b provided in the surface treatment apparatus 10 before coupling are diverted by changing the installation positions.

The surface treatment apparatus 10a coupled in this manner includes plasma treatment devices 21a and 21b and sputtering devices 22a and 22b on both sides of the timing belt 42a, respectively. Therefore, the surface treatment apparatus 10a can perform surface treatment on both surfaces of the workpiece W.

When surface treatment (film deposition) is performed in the order of sputtering and plasma treatment, the surface treatment apparatus 10a conveys the workpiece W, for example, in the order of the sputtering device 22a, the plasma treatment device 21a, the sputtering device 22b, and the plasma treatment device 21b, and performs the surface treatment on both surfaces of the workpiece W. Further, when the surface treatment (film deposition) is performed in the order of the plasma treatment and the sputtering, the workpiece W is conveyed, for example, in the order of the plasma treatment device 21b, the sputtering device 22b, the plasma treatment device 21a, and the sputtering device 22a, and the surface treatment is performed on both surfaces of the workpiece W.

### [7. Connection of Load Lock Chamber]

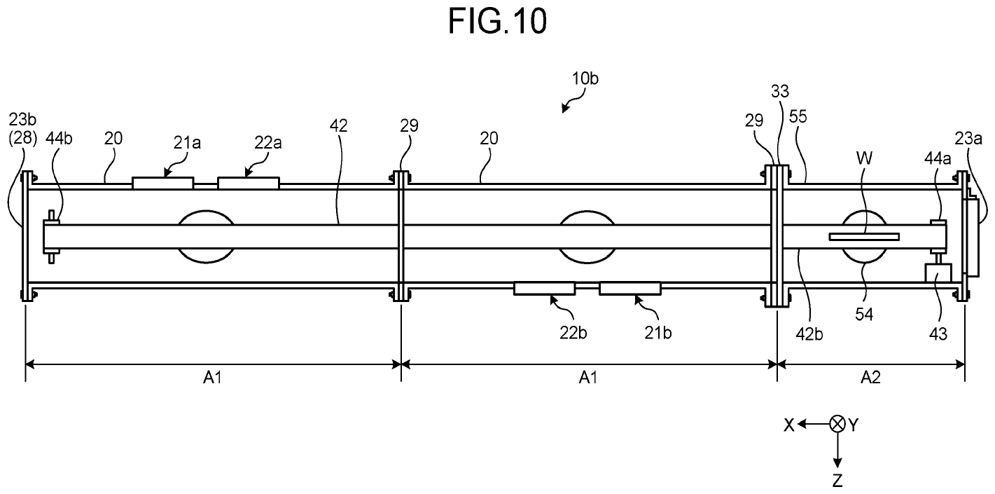

The surface treatment apparatus 10b in which a load lock chamber 55 is coupled to the surface treatment apparatus 10a will be described by using FIG. 10. FIG. 10 is a top view illustrating an example of a state where the load lock chamber is coupled to the surface treatment apparatus illustrated in FIG. 9. The load lock chamber 55 is connected to the chamber 20 via an openable shutter 33 illustrated in FIG. 10. The load lock chamber 55 houses the workpiece W before being subjected to the surface treatment (film deposition treatment) and decompresses the inside thereof to remove atmospheric components adhering to the workpiece W. Further, the workpiece W having completed the film deposition treatment is moved to the load lock chamber 55, and then the pressure of an inside of the load lock chamber 55 is increased to the atmospheric pressure, and thereafter taken out from the load lock chamber 55. As described above, by using the load lock chamber 55, the film deposition treatment can be performed without exposing the workpiece W to the atmosphere. Note that the load lock chamber 55 is an example of a first housing part in the present disclosure.

The chamber 20 and the load lock chamber 55 are fastened to the flanges 24 formed at respective ends, by bolts 26a and nuts 26b (see FIG. 9).

As illustrated in FIG. 10, the load lock chamber 55 (first housing part) and the chamber 20 (second housing part) have different lengths in the conveyance direction (X-axis direction in FIG. 10) of the workpiece conveyance part 40. In the example of FIG. 10, while the two chambers 20 are full-size chambers, the load lock chamber 55 is a half-size chamber having a half-length of the full-size chamber. In other words, the length A1 of the chamber 20 along the X-axis is twice the length A2 of the load lock chamber 55 along the X-axis. Further, although not illustrated, a chamber having a special size may be used. As described above, by setting the size of the housing part in accordance with the function, the attachment table, the pipe, and the like can be commonly used, so that the housing part can be modularized in accordance with the size of the workpiece W and the content of the surface treatment. In particular, when the full-size chamber and the half-size chamber are used, one space of the full-size chamber can be replaced with two half-size chambers, and thus the surface treatment apparatus can be efficiently reconstructed.

The frame member 29 and the shutter 33 described above are provided between the chamber 20 and the load lock chamber 55. The frame member 29 serves to suppress bending deformation when the chamber 20 and the load lock chamber 55 are coupled. The shutter 33 has a function of a gate valve that partitions the load lock chamber 55 and the chamber 20. For example, by moving along the Y-axis, the shutter 33 brings the chamber 20 and the load lock chamber 55 into a communicating state or a non-communicating state.

Note that the load lock chamber 55 includes a lifting valve 54 at a bottom part. The lifting valve 54 has a function similar to that of the lifting valve 53 included in the chamber 20. Then, the lifting valve 53 controls the pressure of the inside of the load lock chamber 55 and discharges the gas filling the inside by cooperating with a pump part that is not illustrated in FIG. 10.

When the load lock chamber 55 is coupled, the surface treatment apparatus 10b is provided with a timing belt 42b for conveying the workpiece W between the load lock chamber 55 and the two coupled chambers 20. In this case, the conveyance motor 43 and the pulleys 44a and 44b provided in the surface treatment apparatus 10a are diverted by changing the installation positions. The timing belt 42b stretched between the two pulleys 44a and 44b is moved along the X-axis by the rotational driving force of the conveyance motor 43, so that the workpiece W placed on the workpiece placement part 50 (see FIG. 1) is conveyed in the longitudinal direction of the load lock chamber 55 and the chamber 20.

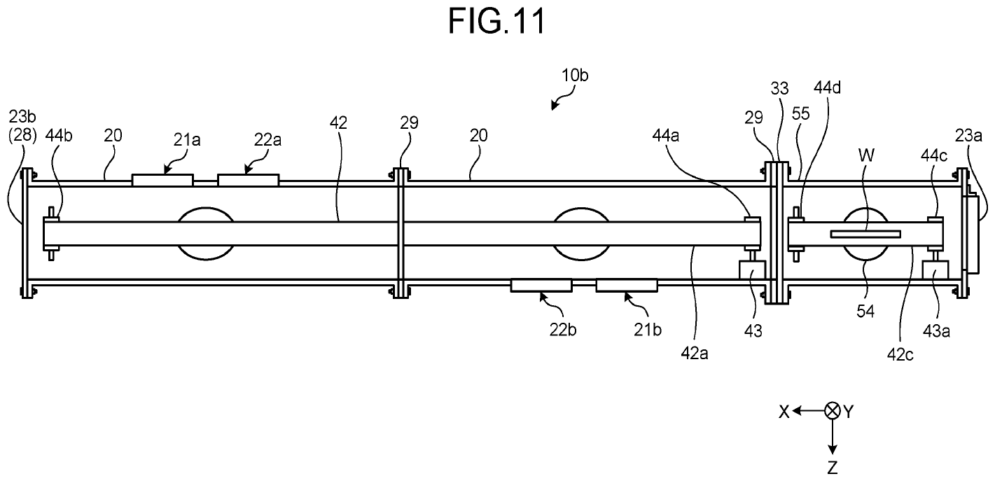

Note that the surface treatment apparatus 10b may have a configuration illustrated in FIG. 11. FIG. 11 is a top view illustrating another example of a state where the load lock chamber is coupled to the surface treatment apparatus illustrated in FIG. 9.

The surface treatment apparatus 10b illustrated in FIG. 11 includes a timing belt 42c inside the load lock chamber 55. The timing belt 42c moves the workpiece W in an X-axis positive direction inside the load lock chamber 55. Note that the timing belt 42c is stretched between a pulley 44c and a pulley 44d. The pulley 44c is driven to rotate by a conveyance motor 43a provided on the negative side of the X-axis. The pulley 44d is provided on the negative side of the X-axis.

The pulley 44a, which is installed inside the chamber 20 and around which the timing belt 42a is fitted, is located close to the pulley 44d. Therefore, the workpiece W having moved inside the load lock chamber 55 is transferred from the timing belt 42c to the timing belt 42a. Then, the workpiece W is moved inside the coupled chambers 20 by the timing belt 42a. In order to enhance airtightness between the load lock chamber and the chambers, it is preferable to provide the separated conveyance devices in this manner.

Note that, although not illustrated, a conveyance arm may be provided inside the load lock chamber 55, and the workpiece W may be moved onto the timing belt 42a by the conveyance arm. Also in this case, airtightness between the load lock chamber and the chambers can be enhanced.

### [8. Structure of Exhaust Device]

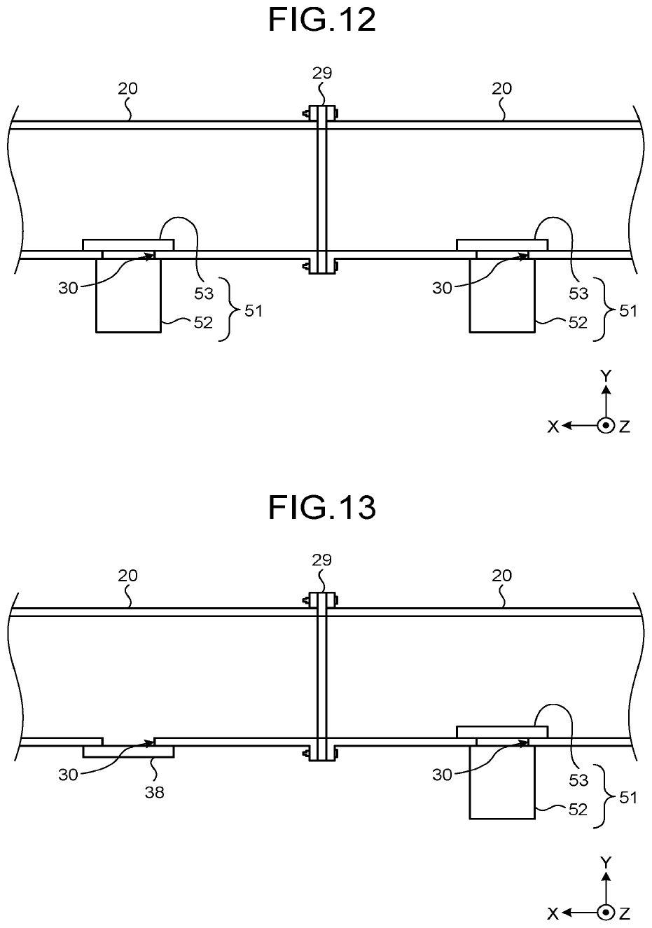

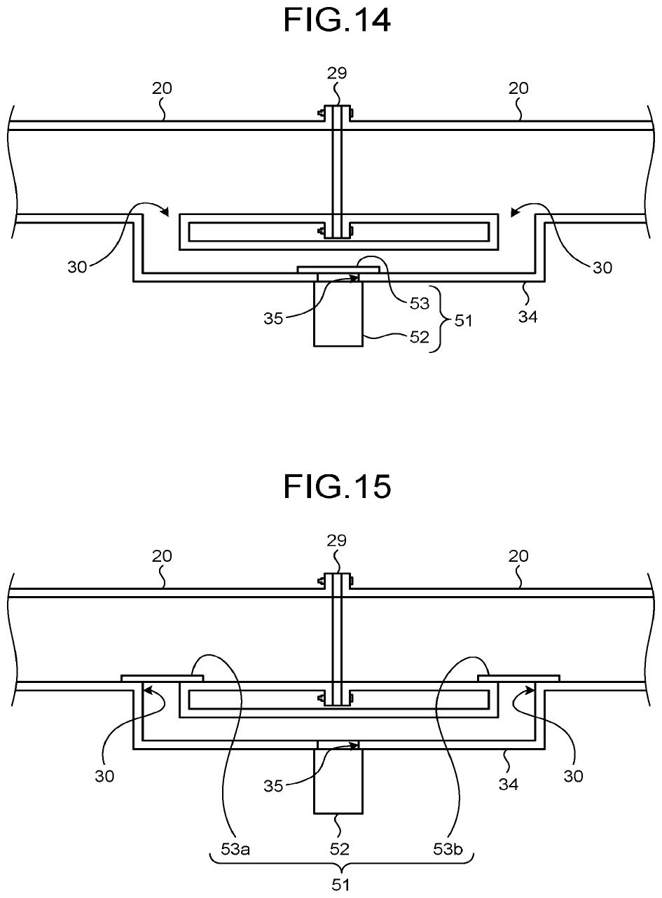

By using FIGS. 12 to 15, a structure of the exhaust device provided in the surface treatment apparatuses 10a and 10b will be described. FIG. 12 is a view illustrating an example of a configuration in which each of coupled surface treatment apparatuses includes the exhaust device. FIG. 13 is a view illustrating an example of a configuration in which one of the coupled surface treatment apparatuses includes the exhaust device. FIG. 14 is a view illustrating an example of a configuration in which the exhaust device is provided on a piping member that couples openings of the coupled surface treatment apparatuses to each other. FIG. 15 is a view illustrating an example of a configuration in which the pump part is provided on the piping member that couples the openings of the coupled surface treatment apparatuses to each other, and a lifting valve is provided in each of the openings of the surface treatment apparatuses.

As described above, there are various variations in the method of installing the exhaust device, and any of them may be used.

First, a configuration of the exhaust device 51 illustrated in FIG. 12 will be described. As described above, the exhaust device 51 illustrated in FIG. 12 includes the pump part 52 and the lifting valve 53, and is installed on the opening 30 of each chamber 20.

The exhaust device 51 installed on each chamber 20 operates independently or individually to open the opening 30 to the atmosphere and discharge the gas filling the inside of the chamber 20.

Note that, although not illustrated in FIG. 12, each chamber 20 may be individually partitioned by installing an openable shutter at a coupling position of the chambers 20. In this case, power saving can be achieved by operating only the exhaust device 51 installed on the partitioned chamber 20.

Next, a configuration of the exhaust device 51 illustrated in FIG. 13 will be described. The exhaust device 51 illustrated in FIG. 13 includes the pump part 52 and the lifting valve 53, and is installed in only one chamber 20. Then, a blank panel 38 is installed on the opening 30 of the chamber 20 on which the exhaust device 51 is not installed.

The exhaust device 51 opens the opening 30 of the chamber 20 on which the exhaust device 51 is installed to the atmosphere, and discharges the gas filling the inside of the chambers 20.

Next, a configuration of the exhaust device 51 illustrated in FIG. 14 will be described. The exhaust device 51 illustrated in FIG. 14 includes the pump part 52 and the lifting valve 53. The exhaust device 51 is installed on an opening 35 provided in a piping member 34 that connects the openings 30 of the coupled chambers 20.

The exhaust device 51 opens the opening 35 of the piping member 34 on which the exhaust device 51 is installed to the atmosphere, and discharges the gas filling the inside of the chambers 20. Note that the piping member 34 is attached to the opening 30 of each chamber 20 when the chambers 20 are coupled. Further, although the piping member 34 illustrated in FIG. 14 connects the two openings 30, when three or more chambers 20 are connected, a piping member that connects three or more openings 30 is used.

Next, a configuration of the exhaust device 51 illustrated in FIG. 15 will be described. The exhaust device 51 illustrated in FIG. 15 includes the pump part 52 and lifting valves 53a and 53b respectively installed in the opening 30 of each chamber 20.

The exhaust device 51 opens the opening 30 of the chamber 20 in which the lifting valves 53a and 53b are installed to the atmosphere, and discharges the gas filling the inside of the chamber 20.

Note that, although not illustrated in FIG. 15, each chamber 20 may be individually partitioned by installing an openable shutter at a coupling position of the chambers 20. In this case, only the gas filling the inside of the partitioned chamber 20 can be discharged by operating only the lifting valve installed in the opening 30 of the partitioned chamber 20, so that power saving can be achieved. Note that, as described above, conveyance of the workpiece W between the different chambers 20 may be performed between the respective timing belts installed in the individual chambers 20, or may be performed by using the conveyance arm.

### [9. First Modification of Embodiment]

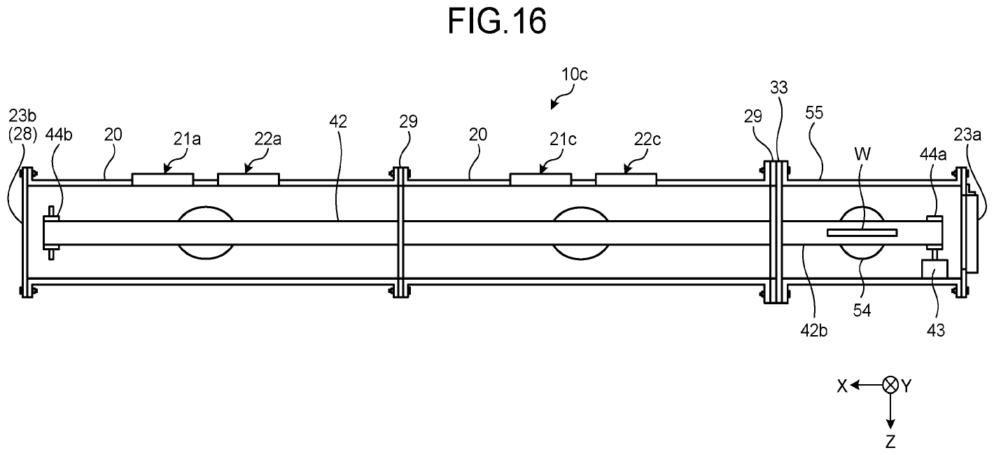

Next, a surface treatment apparatus 10c that is a first modification of the embodiment will be described by using FIG. 16. FIG. 16 is a top view illustrating an example of a schematic configuration of a surface treatment apparatus that is the first modification of the embodiment.

In the surface treatment apparatus 10c, two chambers 20 are coupled without changing the direction, and a load lock chamber 55 is further coupled.

The surface treatment apparatus 10c performs multiple times of surface treatment (film deposition) only on one surface of the workpiece W.

Specifically, when surface treatment (film deposition) is performed in the order of sputtering and plasma treatment, the surface treatment apparatus 10c conveys the workpiece W toward, for example, a sputtering device 22c, a plasma treatment device 21c, the sputtering device 22a, and the plasma treatment device 21a in this order to perform the surface treatment on one surface of the workpiece W. Further, when the surface treatment (film deposition) is performed in the order of the plasma treatment and the sputtering, the workpiece W is conveyed toward, for example, the plasma treatment device 21c, the sputtering device 22c, the plasma treatment device 21a, and the sputtering device 22a in this order to perform the surface treatment on one surface of the workpiece W. Note that by setting the attachment dimensions of the plasma treatment devices 21a and 21c and the sputtering devices 22a and 22c to the chamber 20 to be the same, for example, it is possible to freely combine them such as installing one plasma treatment device and three sputtering devices.

Note that, in FIG. 16, the workpiece W may be conveyed between the load lock chamber 55 and the chamber 20 by being delivered between respective timing belts independently installed in the load lock chamber 55 and the chamber 20.

### [10. Second Modification of Embodiment]

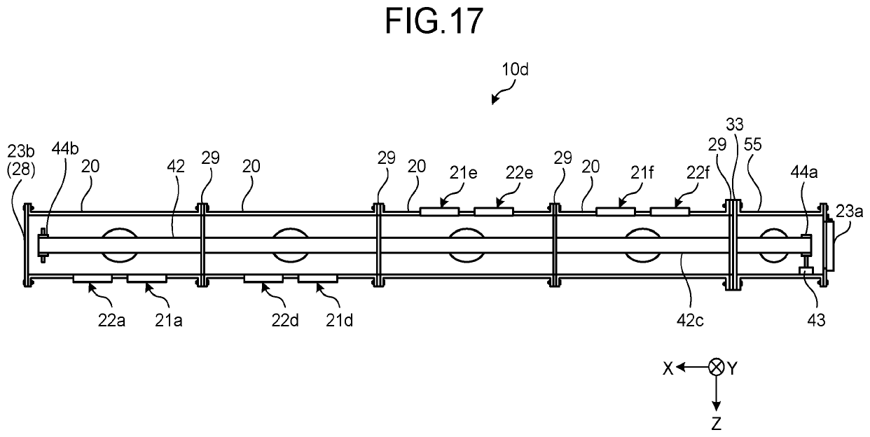

Next, a surface treatment apparatus 10d that is a second modification of the embodiment will be described by using FIG. 17. FIG. 17 is a top view illustrating an example of a schematic configuration of a surface treatment apparatus that is the second modification of the embodiment.

The surface treatment apparatus 10d is obtained by coupling four chambers 20 and a load lock chamber 55.

The surface treatment apparatus 10d performs multiple times of surface treatment (film deposition) on each of both surfaces of the workpiece W.

Specifically, when surface treatment (film deposition) is performed in the order of sputtering and plasma treatment, the surface treatment apparatus 10d conveys the workpiece W toward, for example, a sputtering device 22f, a plasma treatment device 21f, a sputtering device 22e, a plasma treatment device 21e, a sputtering device 22d, a plasma treatment device 21d, the sputtering device 22a, and the plasma treatment device 21a in this order to perform surface treatment on both surfaces of the workpiece W. Further, when the surface treatment (film deposition) is performed in the order of the plasma treatment and the sputtering, the workpiece W is conveyed toward, for example, the plasma treatment device 21f, the sputtering device 22f, the plasma treatment device 21e, the sputtering device 22e, the plasma treatment device 21d, the sputtering device 22d, the plasma treatment device 21a, and the sputtering device 22a in this order to perform the surface treatment on both surfaces of the workpiece W.

Note that, in FIG. 17, the workpiece W may be conveyed between the load lock chamber 55 and the chamber 20 by being delivered between respective timing belts independently installed in the load lock chamber 55 and the chamber 20.

### [11. Third Modification of Embodiment]

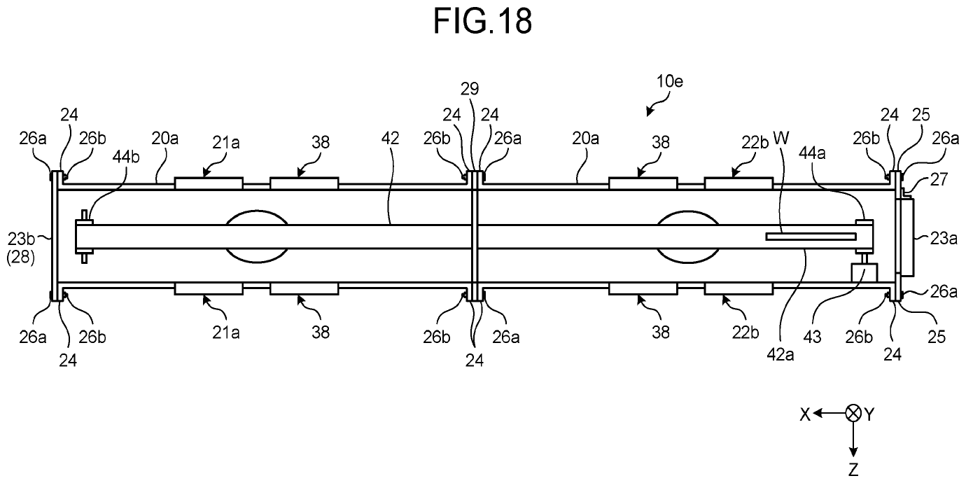

Next, a surface treatment apparatus 10e that is a third modification of the embodiment will be described by using FIG. 18. FIG. 18 is a top view illustrating an example of a schematic configuration of a surface treatment apparatus that is the third modification of the embodiment.

The surface treatment apparatus 10e is obtained by coupling two chambers 20a through the frame member 29. In each of the chambers 20a, two hole-shaped attachment positions where the surface treatment part can be installed are formed at the same position in the X-axis direction in the longitudinal direction (conveyance direction of the workpiece W) so as to face the surface of the workpiece W.

Then, in the example of FIG. 18, the sputtering device 22b, the blank panel 38, the blank panel 38, and the plasma treatment device 21a are installed in this order toward the positive side of the X-axis at the attachment position where the surface treatment part can be installed.

Specifically, in the chamber 20a on the negative side of the X-axis direction in FIG. 18, the sputtering device 22b is installed at one of the hole-shaped attachment positions where the surface treatment part can be installed, and the blank panel 38 is installed at the other one. Then, in the chamber 20a on the positive side of the X-axis direction in FIG. 18, the plasma treatment device 21a is installed at one of the hole-shaped attachment positions where the surface treatment part can be installed, and the blank panel 38 is installed at the other one.

As described above, the attachment positions where the surface treatment part can be installed are provided in the chamber 20a, and an appropriate surface treatment part can be installed in accordance with the content of the surface treatment to be performed on the workpiece W. Then, a position where the surface treatment part is not provided can be performed by the blank panel 38. Therefore, a desired surface treatment can be performed on both surfaces of the workpiece W.

### [12. Fourth Modification of Embodiment]

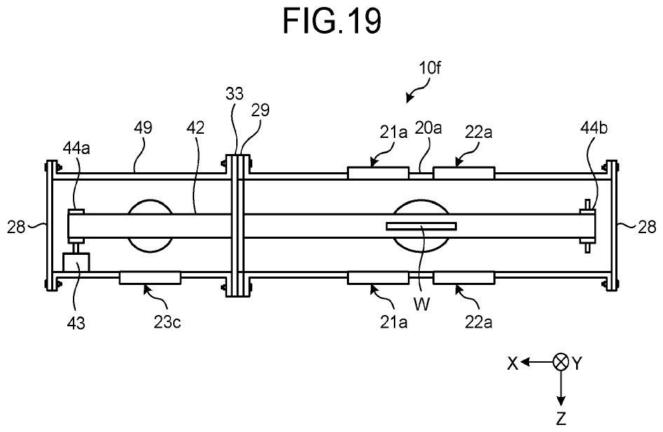

Next, a surface treatment apparatus 10f that is a fourth modification of the embodiment will be described by using FIG. 19. FIG. 19 is a top view illustrating an example of a schematic configuration of a surface treatment apparatus that is the fourth modification of the embodiment.

The surface treatment apparatus 10f is obtained by coupling one chamber 20a and one door part 49 via the frame member 29 and the shutter 33.

In FIG. 19, in the chamber 20a, the plasma treatment device 21a and the sputtering device 22a are installed so as to face each of both surfaces of the workpiece W in the longitudinal direction (conveyance direction (X-axis) of the workpiece W).

The door part 49 is a housing part including an opening-closing door 23c through which the workpiece W can be taken in and out. The opening-closing door 23c is installed on a side surface along the X-axis. Note that the door part 49 is an example of the first housing part in the present disclosure.

The surface treatment apparatus 10f starts the surface treatment from a state where the workpiece W is housed in the door part 49. Then, after the surface treatment is performed in the chamber 20a, the conveyance direction is reversed, and the workpiece W is returned to the position of the door part 49. When the workpiece W is returned, another surface treatment may be performed. Thereafter, the workpiece W having completed the surface treatment is taken out from the opening-closing door 23c.

Note that, instead of installing the door part 49, the same function as FIG. 19 can be achieved also by configuring a surface treatment apparatus in which a turning part having the same shape as the door part 49 and not including the opening-closing door 23c is installed, and the opening-closing door 23c is installed at the position of the blank panel 28 installed in the chamber 20a of FIG. 19. In this case, the workpiece W is taken in and out by opening the opening-closing door 23c installed in the chamber 20a.

Further, in FIG. 19, a configuration may be employed in which the door part 49 or the turning part is connected to each of both ends of the chamber 20a via the frame member 29 and the shutter 33. In such a configuration, the volume of the chamber 20a can be increased in the longitudinal direction (X-axis direction) by communicating the chamber 20a with the two door parts 49 or the two turning parts in a state where the shutter 33 is opened. Thus, the workpiece W having a large area (long length) can pass from end to end through the surfaces of the plasma treatment device 21a and the sputtering device 22a. Therefore, the surface treatment can be performed on the long workpiece W.

### [13. Operation and Effect of Embodiment]

As described above, the surface treatment apparatus 10a according to the present embodiment includes: the workpiece placement part 50 (placement part) on which the workpiece W is placed; the load lock chamber 55 (first housing part) that houses the workpiece W placed on the workpiece placement part 50; the chamber 20 (second housing part) that houses the workpiece W placed on the workpiece placement part 50 and includes the surface treatment part (plasma treatment device 21 or sputtering device 22) that performs at least one type of surface treatment; and the workpiece conveyance part 40 (conveyance part) that conveys the workpiece W placed on the workpiece placement part 50 in the longitudinal direction of the load lock chamber 55 or the chamber 20, and surface treatment is performed on the workpiece W in a state where the chamber 20 is a single body or in a state where the load lock chamber 55 and the chamber 20 are plurally coupled in a conveyance direction of the workpiece conveyance part 40. Therefore, film deposition conditions of a single-sided film deposition apparatus can be directly applied to a double-sided film deposition apparatus. Further, the surface treatment can be performed without exposing the workpiece W to the atmosphere. Moreover, the coupled state of the chambers 20 matching the content of the surface treatment to be performed can be achieved, whereby it is possible to reduce the amount of film deposition gas and electric power used for the surface treatment, and it is possible to flexibly cope with the content of the surface treatment to be performed.

Additionally, in the surface treatment apparatus 10a of the present embodiment, different housing parts are coupled by the frame member 29 formed by a rigid body, the frame member including an outer frame abutting on an outer edge of the load lock chamber 55 (first housing part) or the chamber 20 (second housing part). Therefore, the rigidity of the surface treatment apparatus 10a can be increased. Further, it is possible to prevent occurrence of air leakage from the connection part between the chambers 20.

Additionally, in the surface treatment apparatus 10a of the present embodiment, lengths of the load lock chamber 55 (first housing part) and the chamber 20 (second housing part) in the conveyance direction of the workpiece conveyance part 40 (conveyance part) have multiple sizes. Therefore, for example, when the chamber 20 is a full-size chamber and the load lock chamber 55 is a half-size chamber whose length in the conveyance direction is half the length of the full-size chamber, one space of the full-size chamber can be replaced with two half-size chambers, the surface treatment apparatus can be efficiently reconstructed, and the attachment table, piping, and the like of the surface treatment apparatus 10a can be commonly used.

Additionally, in the surface treatment apparatus 10a of the present embodiment, the surface treatment part includes the plasma treatment device 21 that performs surface treatment of the workpiece W by irradiating the workpiece W with plasma, or the sputtering device 22 that performs sputtering on the workpiece W. Therefore, an appropriate film deposition treatment can be performed on the workpiece W.

Additionally, in the surface treatment apparatus 10a of the present embodiment, when the chambers 20 (second housing parts) are coupled, the same or different types of surface treatment parts (plasma treatment device 21 or sputtering device 22) are installed in each of the chambers 20. Therefore, the content of the surface treatment to be performed on the workpiece W can be freely set.

Additionally, in the surface treatment apparatus 10a of the present embodiment, the chambers 20 (second housing parts) are coupled without changing the directions of the surface treatment parts (plasma treatment devices 21 or sputtering devices 22) included in the chamber 20. Therefore, single-sided film deposition regardless of the number of layers to be formed can be easily achieved.

Additionally, in the surface treatment apparatus 10a of the present embodiment, the chambers 20 (second housing parts) are coupled by reversing the directions of the surface treatment parts (plasma treatment devices 21 or sputtering devices 22) included in the chamber 20. Therefore, double-sided film deposition regardless of the number of layers to be formed can be easily achieved.

Additionally, in the surface treatment apparatus 10a of the present embodiment, the load lock chamber 55 is coupled to the chamber 20 (second housing part). Therefore, the surface treatment can be performed without exposing the workpiece W to the atmosphere.

Additionally, in the surface treatment apparatus 10a of the present embodiment, the workpiece conveyance part 40 (conveyance part) changes a conveying range of the workpiece W in accordance with a coupling state between the chambers 20 (second housing parts). Therefore, the workpiece W can be conveyed in accordance with the coupled state of the chamber 20.

Additionally, in the surface treatment apparatus 10a of the present embodiment, each of the load lock chamber 55 (first housing part) and the chamber 20 (second housing part) includes the exhaust device 51 (exhaust part) that adjusts the pressure of the inside and discharges the gas filling the inside. Therefore, multiple different types of surface treatment can be performed without exposing the workpiece W to the atmosphere.

Additionally, in the surface treatment apparatus 10a of the present embodiment, the exhaust device 51 (exhaust part) includes at least one pump part 52 (pump device) that sucks gas inside the chamber 20 (second housing part), the lifting valve 53 (valve member) that opens and closes the opening 30 included in the chamber 20, and the piping member 34 that connects the pump part 52 and the opening 30. Therefore, the inside of the chamber 20 can be exhausted regardless of the coupled state of the chamber 20.

Moreover, the surface treatment apparatus 10a of the present embodiment further includes shutters 31 and 32 (shielding members) that, when one of the surface treatment parts (plasma treatment device 21 or sputtering device 22) performs the surface treatment on the workpiece W, each shield a surface treatment part different from the surface treatment part. Therefore, it is possible to prevent contamination of the electrode constituting the surface treatment part that is not involved in the surface treatment.

Although the embodiments of the present invention have been described above, the above-described embodiments have been presented as examples, and are not intended to limit the scope of the present invention. This novel embodiment can be implemented in various other forms. Further, various omissions, substitutions, and changes can be made without departing from the gist of the invention. Moreover, this embodiment is included in the scope and gist of the invention, and is included in the invention described in the claims and the equivalent scope thereof.

### EXPLANATIONS OF LETTERS OR NUMERALS

10, 10a, 10b . . . surface treatment apparatus; 20, 20a . . . chamber (second housing part); 21, 21a, 21b, 21c, 21d, 21e, 21f . . . plasma treatment device (surface treatment part); 22, 22a, 22b, 22c, 22d, 22e, 22f . . . sputtering device (surface treatment part); 23a, 23b, 23c . . . opening-closing door; 24 . . . flange; 25 . . . door frame; 26a . . . bolt; 26b . . . nut; 27 . . . hinge; 28, 38 . . . blank panel; 29 . . . frame member; 30, 35 . . . opening; 31, 32 . . . shutter (shielding member); 33 . . . shutter; 34 . . . piping member; 40 . . . workpiece conveyance part (conveyance part); 41 . . . moving table; 42, 42a, 42b, 42c . . . timing belt; 43, 43a . . . conveyance motor; 44a, 44b, 44c, 44d . . . pulley; 46 screw; 47 . . . attachment table; 48 . . . attachment shaft; 49 . . . door part (first housing part); 50 workpiece placement part (placement part); 51 . . . exhaust device (exhaust part); 52 . . . pump part (pump device); 53, 54 . . . lifting valve (valve member); 55 . . . load lock chamber (first housing part); 56 . . . gas flow path; 57 . . . gas supply hole; 58 . . . gas supply pipe attachment member; 59 . . . support member; 60, 62 . . . plate-shaped conductor part (electrode); 61 . . . gap part; 63 . . . spacer; 64, 77 . . . support plate; 66 . . . gas supply pipe; 67 . . . recess; 69, 70 . . . through hole; 73 . . . matching box (MB); 74 . . . high frequency power supply (RF); 75 . . . ground; 76a, 76b . . . mass flow controller (MFC); 78 . . . gas supply part; 79, 88 . . . holding member; 80 . . . gas introduction part; 81 . . . cooling water pipe; 82 . . . cooling water passage; 83 . . . support plate; 84 . . . magnet; 85 . . . cooling jacket; 86 . . . insulating material; 87 . . . target; 90 . . . port; 91, 92 . . . base material holder; 91a . . . attachment hole; 93a, 93b . . . gas supply pipe; 94 . . . gas supply hole; 141 . . . attachment flange; 143 . . . driving means support part; 150 . . . flow rate regulating valve; 151 . . . flow path part; 160 . . . servo actuator; 161 . . . worm jack; 162 . . . lifting shaft; 163 . . . coupling member; 165 . . . valve guide; 166 . . . guide engagement part; 170 . . . turbo molecular pump; 171 . . . pump flange; 210 . . . . HCD electrode; 220 . . . sputtering electrode; W . . . workpiece

1. A surface treatment apparatus comprising:
a placement part on which a workpiece is placed;
a first housing part that houses the workpiece placed on the placement part;
a second housing part that houses the workpiece placed on the placement part and includes a surface treatment part performing at least one type of surface treatment; and
a conveyance part that conveys the workpiece placed on the placement part in a longitudinal direction of the first housing part or the second housing part,
wherein the surface treatment apparatus performs surface treatment on the workpiece in a state where the second housing part is a single body or in a state where the first housing part and the second housing part are plurally coupled in a conveyance direction of the conveyance part.

2. The surface treatment apparatus according to claim 1, wherein different housing parts are coupled by a frame member being a rigid body, the frame member including an outer frame abutting on an outer edge of the first housing part or the second housing part.

3. The surface treatment apparatus according to claim 1, wherein lengths of the first housing part and the second housing part in the conveyance direction of the conveyance part have multiple sizes.

4. The surface treatment apparatus according to claim 3, wherein the first housing part and the second housing part each have two types of lengths in the conveyance direction of the conveyance part, one of the lengths being half of the other length.

5. The surface treatment apparatus according to claim 1, wherein the surface treatment part includes a plasma treatment device or a sputtering device, the plasma treatment device performing surface treatment of the workpiece by irradiating the workpiece with plasma, the sputtering device performing sputtering on the workpiece.

6. The surface treatment apparatus according to claim 1, wherein, when the different second housing parts are coupled, same or different types of surface treatment parts are installed in each of the second housing parts.

7. The surface treatment apparatus according to claim 1, wherein the second housing parts are coupled in such a manner that directions of respective surface treatment parts included in the second housing parts are equal to each other.

8. The surface treatment apparatus according to claim 1, wherein the second housing parts are coupled in such a manner that directions of respective surface treatment parts included in the second housing parts are reversed.

9. The surface treatment apparatus according to claim 1, wherein the first housing part is a load lock chamber.

10. The surface treatment apparatus according to claim 1, wherein the conveyance part changes a conveyance range of the workpiece in accordance with a coupling state between the first housing part and the second housing part.

11. The surface treatment apparatus according to claim 1, wherein each of the first housing part and the second housing part includes an exhaust part that adjusts a pressure of an inside of the first housing part and the second housing part and discharges gas filling the inside of the first housing part and the second housing part.

12. The surface treatment apparatus according to claim 11, wherein
the exhaust part includes:
at least one pump device that sucks gas inside the first housing part or the second housing part;
a valve member that opens and closes an opening provided in the first housing part or the second housing part; and
a piping member that connects the pump device and the opening.

13. The surface treatment apparatus according to claim 1, wherein
the second housing part further includes a shielding member that, when one of the surface treatment parts performs surface treatment on the workpiece, shields a surface treatment part that is different from the one of the surface treatment parts and is set in a same second housing part.
